(19) United States
(12) Patent Application Publication
(10) Pub. No.: US 2004/0126983 A1
(43) Pub. Date: Jul. 1, 2004

(54) Method for forming capacitor in semiconductor device

(76) Inventor: Yong-Soo Kim, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/621,870

(22) Filed: Jul. 17, 2003

(30) Foreign Application Priority Data
Dec. 30, 2002 (KR) 2002-86498

(51) Int. Cl. H01L 21/8234; H01L 21/8244; H01L 21/8242; H01L 21/20

(52) U.S. Cl. 438/396; 438/253

(57) ABSTRACT

The present invention provides a method for forming a capacitor in a semiconductor device. Particularly, an aluminum oxide (Al₂O₃) layer deposited by using an atomic layer deposition (ALD) process is used for the capacitor. The inventive method for forming the capacitor, including; forming a lower electrode constituted with a poly-silicon layer on a semiconductor substrate a predetermined process on which a predetermined process has been completed; forming a uniform silicon oxide layer on the lower electrode; forming an aluminum oxide (Al₂O₃) film on the silicon oxide layer by performing an atomic layer deposition (ALD) process; and crystallizing the Al₂O₃ film by carrying out a heat treatment process.

### FIELD OF THE INVENTION

The present invention relates to a method for forming a capacitor in a semiconductor device; and, more particularly, to a method for forming a capacitor with use of an aluminum oxide (Al₂O₃) layer deposited by an atomic layer deposition (ALD) process.

### DESCRIPTION OF THE RELATED ART

Generally, a capacitor used for a memory cell is constituted with a lower electrode for a storage node, a dielectric layer and an upper electrode for a plate. In addition, a capacitance of about 25 fF per a cell is required to operate a semiconductor device having a reduced cell area for a large scale integration technology. For this effect, methods for increasing a capacitor height and a capacitor area by forming a meta-stable polysilicon (MPS), decreasing a thickness of a dielectric film and forming a ferroelectric film.

However, it is difficult to increase capacitor beyond a certain height because of an etching limit, and the thickness of the dielectric film can not be reduced below a certain thickness because of a current leakage. To alleviate the obstacles mentioned above, a method for obtaining a capacitance corresponding to the large scale integration technology is contrived through the development of ferroelectric films such as tantalum oxide (Ta₂O₅) film, aluminum oxide (Al₂O₃) film and SrBi₂Ta₂O₉ (SBT) film. However, deposition methods and source materials for forming the ferroelectric films except for the Ta₂O₅ film and the Al₂O₃ and their effects on a semiconductor device property should be carefully studied in more extents. The Ta₂O₅ film has a dielectric constant ranging from about 20 to about 25. However, in case of applying it to a metal-insulator-silicon (MIS) structure, the Ta₂O₅ having a real thickness T_{eqox} less than 35 Å has an inferior current leakage property and a poor compatibility for a future semiconductor device. Accordingly, the Al₂O₃ film having a high off-set value of a valence band for a poly-silicon is applied to the MIS structure or a silicon-insulator-silicon (SIS) structure although the Al₂O₃ film has a dielectric constant ε of about 9 lower than the Ta₂O₅ does. Herein, a current leakage property of the Al₂O₃ film is not changed although the T_{eqox} is reduced due to the high off-set value of the valence band.

Usually, the Al₂O₃ film is formed through the use of an atomic layer deposition (ALD) process employing a trimethlyaluminum (TMA), that is, Al(CH₃)₃ as a aluminum source gas and an aqueous vapor H₂O or O₃/H₂O₂ as a reaction gas. At this time, the deposited Al₂O₃ is amorphous, and therefore, a heat treatment process is carried out to crystallize the amorphous Al₂O₃ film at a high temperature more than about 850° C. However, as shown in FIG. 1, if a lower electrode 10 of the capacitor having the MIS or SIS structure is formed with an N-type doped poly-silicon and the Al₂O₃ film 11 is deposited on an upper area of the lower electrode 10, an SiₓO_{y} 100 interfacial oxide film is formed between the upper area of the lower electrode and the Al₂O₃ film through an OH-bond inside the Al₂O₃ film 11 and an exchange reaction of the N-type doped poly-silicon during the heat treatment process. Consequently, the capacitor capacitance of the capacitor and a breakdown voltage property is degraded by the SiₓO_{y} (100) interfacial oxide film.

In addition, an x-ray photoemission spectroscopy (XPS) information is obtained through an XPS analysis as shown in FIG. 2. More specifically, a peak corresponding to an Al—Al bond appears as the XPS analysis gets closer to an interface between the Al₂O₃ 11 and the poly-silicon layer 10. Referring to FIGS. 2(A) and (B) show results of XPS analysis at different positions having a different depth from the lower poly-silicon. Particularly, the XPS analysis is applied to the identical capacitor but to different depths of the Al₂O₃ film. Herein a depth of the case (B) is deeper than that of the case (A). The Al—Al bond is formed because an Al cluster exists inside the Al₂O₃ film. The Al—Al cluster is induced from post thermal treatment. For such reason mentioned above, an incubation time is needed during the ALD process for depositing the Al₂O₃ film because of the Al cluster.

FIG. 3 is a graph showing a thickness of the Al₂O₃ film changed as the number of a cycle is increased as the number of a cycle is increased. As shown, the thickness of the Al₂O₃ film is linearly increased as the cycle number is increased because the ALD process is usually performed in accordance with a surface limited reaction mechanism. However, the Al—Al bond is more easily formed than an Al—O bond during a few initial cycles of the ALD process. Accordingly, the Al cluster is formed inside the Al₂O₃ film. As a result, a leakage path is formed, and thereby, drastically degrading a performance of the semiconductor device.

Furthermore, a cause for an Al cluster generation is related to a surface state of the lower layer on which the Al₂O₃ is formed.

A process for forming the Al2O3 film in accordance with the surface limited reaction mechanism will be explained in conjunction with FIG. 4 and chemical equations. The chemical equations are as the followings.

AlOH*+Al(CH₃)₃→AlOAl(CH₃)₄*+CH₄ Eq. 1

AlCH₃*+H₂O→AlOH*+CH₄ Eq. 2

Herein, a notation, i.e., * means “surface state”.

Referring to FIG. 4(A), if Al(CH₃)₃,i.e., TMA is supplied to an substrate having an surface state OH radical, AlOAl(CH₃)₄* is formed as shown in Eq 1 and FIG. 4(B) and a by-product, i.e., CH₄ is purged out together with a purge gas argon Ar. Also, referring to FIG. 4(C) if H₂O is supplied to the substrate having an surface state AlOAl(CH₃)₄* as shown in FIG. 4(C), AlOH* is formed as shown in the Eq 2 and FIG. 4(D) shows that another by-product CH₄ is purged out together with the purge gas. A series of processes mentioned above constitutes a cycle and a target film thickness is obtained by repeating the cycle. Usually, a surface of a solid material does not have lattice repeatability. Accordingly, the surface of the solid material has a different energy state compared with an inside energy state of the solid material, wherein the different energy state of the surface is called a surface state. Herein, in the surface state, a chemical reaction happens easily because the surface of the solid material is activated.

In short, if the surface state of the lower layer on which the Al₂O₃ film is formed induces a deposition of an impurity such as Si, C, H, or N instead of the AlOH, an oxygen supply deficiency occurs due to a direct inter-reaction between Al and Si instead of the AlOAl(CH₃)₂. Consequently, the Al cluster is formed at the interface. In addition, the Al cluster can be formed through an inter-reaction between electrons existing in the lower layer and Al³⁺ ions of the TMA as well. Especially, if an N⁺ doped poly-silicon layer having sufficient electrons is used, a metallic Al cluster is more easily formed.

### SUMMARY OF THE INVENTION

It is, therefore, an object of the present invention to provide a method for forming a capacitor with use of an aluminum oxide (Al₂O₃) layer deposited by an atomic layer deposition (ALD) process.

In accordance with an aspect of the present invention, there is provided the method for fabricating the capacitor of the semiconductor device, including: forming a lower electrode constituted with a silicon layer on a semiconductor substrate a predetermined process having been completed; forming a uniform silicon oxide layer on the lower electrode by performing an atomic layer deposition (ALD) process; forming an aluminum oxide (Al₂O₃) film on the silicon oxide layer; and crystallizing the Al₂O₃ film by carrying out a heat treatment process.

### BRIEF DESCRIPTION OF THE DRAWINGS

Other objects and aspects of the invention will become apparent from the following description of the embodiments with reference to the accompanying drawings, in which;

FIG. 1 is a cross-sectional view illustrating an interface oxide film formed between a lower electrode constituted with a poly-silicon layer and an Al₂O₃ film during a capacitor formation process in accordance with a prior art.;

FIG. 2 is a graph showing results of an XPS analysis for the Al₂O₃ film deposited on an upper area of the poly-silicon layer in accordance with the prior art;

FIG. 3 is a graph showing a thickness change of the Al₂O₃ film in accordance with the number of an ALD process cycle in accordance with the prior art;

FIG. 4 is a diagram showing process steps for forming the Al₂O₃ film by employing the ALD process in accordance with the prior art;

FIG. 5 is a cross-sectional view showing a method for forming a capacitor in a semiconductor device in accordance with the present invention; and

FIG. 6 is a graph showing a thickness change of Al₂O₃ films deposited in accordance with the number of an ALD process cycle with respect to a species of a lower layer, wherein (A) shows the thickness change of the Al₂O₃ film deposited over a SiO₂ lower layer and (B) shows the thickness change of the Al2O3 film deposited on a poly-silicon layer accordance with the prior art.

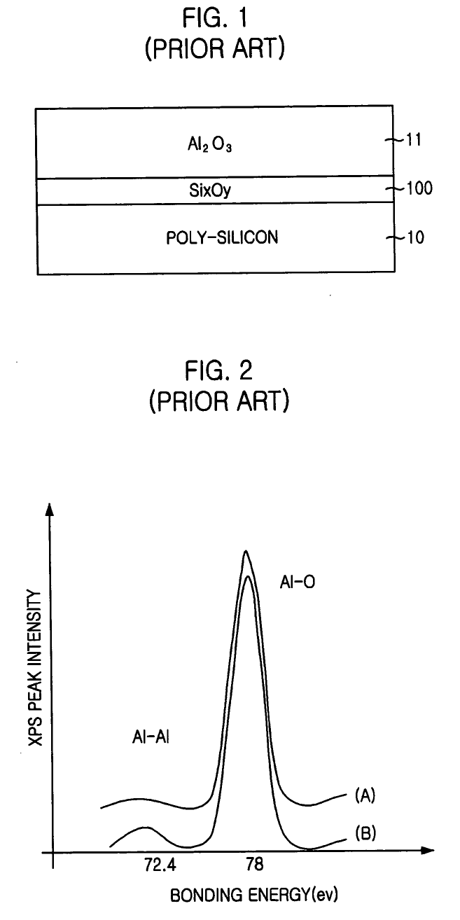

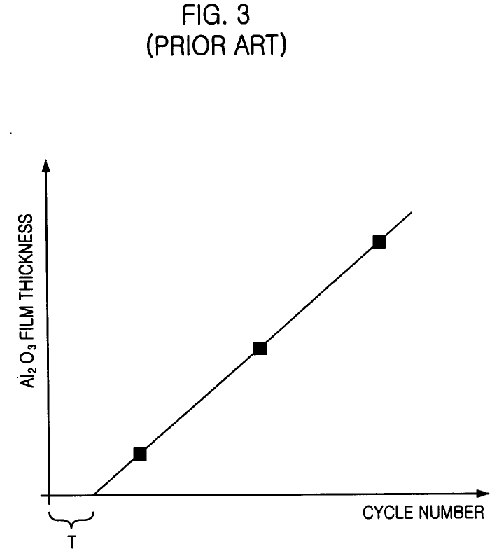

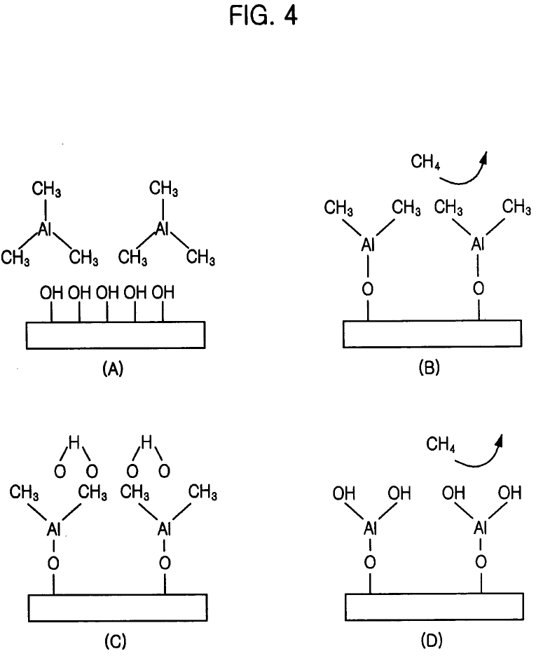

### DETAILED DESCRIPTION OF THE PREFERRED EMBODIMENTS

Hereinafter, an inventive capacitor for a semiconductor device and a method for forming the same will be described in detail referring to the accompanying drawings.

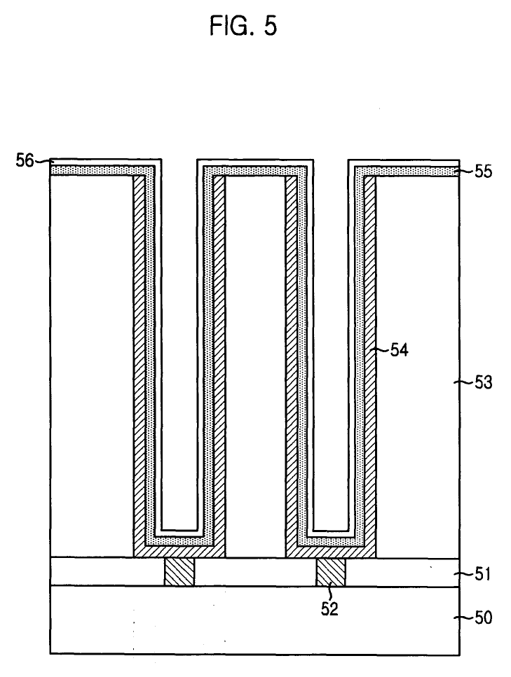

FIG. 5 is a cross-sectional view showing a method for forming a capacitor in a semiconductor device in accordance with a preferred embodiment of the present invention.

Referring to FIG. 5, an inter-layer insulation film 51 is formed on a semiconductor substrate 10, wherein some predetermined processes are completed before forming the inter-layer insulation film 51. A contact hole is formed by etching the inter-layer insulation film 51 for the purpose of exposing a portion of the semiconductor substrate 50. Next, a conductive layer such as a poly-silicon layer is deposited on an upper area of the inter-layer insulation film 51, wherein the conductive layer is buried into the contact hole. As a next step, a chemical mechanical polishing (CMP) process or an etch-back process is carried out to expose a surface of the inter-layer insulation film 51 through a blanket etch process and thereby, completely forming a contact plug 52. Herein, the contact plug 52 is used as a storage node contact.

Next, a capacitor oxide layer 53 constituted with a phosphor-silicate glass (PSG) layer and a plasma enhanced tetra-ethyl-ortho-silicate (PE-TEOS) layer is formed on an entire surface of the semiconductor substrate 50. In addition, a lower electrode 54 is formed on a surface of the contact hole and the capacitor oxide layer 53, and the lower electrode 54 is separated by a blanket-etch process using the CMP process or the etch back process capable of exposing a surface of the capacitor oxide layer 53. Desirably, the lower electrode 54 is formed with a silicon layer such as a undoped poly-silicon layer or a doped amorphous silicon layer. Furthermore, prior to a separation of the lower electrode 54, a meta-stable poly-silicon (MPS) (not shown) is formed on a surface of the lower electrode 54 for the purpose of increasing a surface area of the lower electrode 54. Next, the lower electrode 54 is doped by using PH₃ and a heat treatment process adopting a furnace anneal process is carried out.

Continuously, a silicon oxide SiO₂ layer 55 having a thickness less than about 10 Å is formed on a surface of the lower electrode 54 by performing a catalyst-ALD process adopting an in-situ method or an ex-situ method at a low temperature less than about 200 Å. At this time, the SiO₂ layer 55 formed by employing the ALD process at the low temperature has a uniform thickness. Herein, a variation of the thickness is less than 2 Å. Desirably, the catalyst-ALD process uses a silicon source selected among SiCl₄, SiH₂Cl₂ (DCS) and Si₂Cl₆ (HCD), and one of H₂O, O₃ and H₂O₂ is used as a reaction source. In addition, a pyridine is used as a catalyst at the time that the silicon source and the reaction source are supplied, and each of a supply time and a purge time for the silicon source and the reaction source is less than 10 seconds.

Next, an Al₂O₃ film 56 is formed on the SiO₂ layer 55 by carrying out the ALD process using an Al(CH₃)₃ ,i.e., TMA aluminum source and a reaction source selected among H₂O, O₃, and H₂O₂. Moreover, a heat treatment process for the Al₂O₃ film 56 is carried out to crystallize it. Desirably, a plasma is used as an energy source for the ALD process, and the ALD process is carried out at a room temperature or at a temperature of about 500° C. More precisely, a range from about 200° C. to about 500° C. is most suitable for the ALD process. The Al₂O₃ film has a thickness less than about 100 Å. Also, the heat treatment process for the Al₂O₃ film 56 is performed at a temperature greater than 600° C. in a N₂ or O₂ ambient. Herein, the heat treatment process is performed by adopting a furnace annealing process or a rapid thermal process (RTP). Furthermore, when the Al₂O₃ film is deposited by using the ALD process, the Al₂O₃ film is deposited without any incubation time even at an initial cycle of the ALD process. The reason for this result is because the SiO₂ layer 55 formed on the surface of the lower electrode 54 of the silicon layer has a superior surface uniformity.

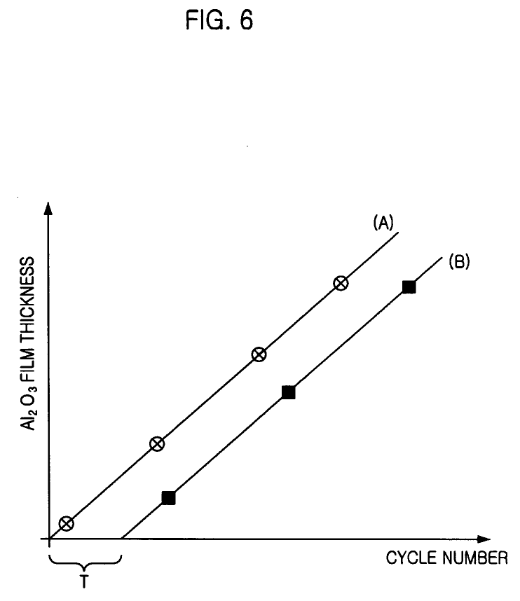

FIG. 6 is a graph showing a thickness change of the Al₂O₃ film formed in accordance with the number of the ALD process with respect to a species of the lower layer. According to the FIG. 6, in case of the lower layer formed with the SiO₂ layer (A), the incubation time is not needed. However, the incubation time is needed for the lower layer formed with a poly-silicon layer (B). Also, even though not illustrated, if an X-ray photoemission spectroscopy (XPS) analysis of the Al₂O₃ film 56 formed on the SiO₂ layer 55 reveals that that a metallic aluminum (Al) cluster is not formed at an interface between the Al₂O₃ film 56 and the SiO₂ layer 55. Furthermore, an interface oxide such as SiₓO_{y} is not formed by the SiO₂ film during the heat treatment process for the Al₂O₃ film 56.

As a next step, an upper electrode is formed on the Al₂O₃ film 56 and thereby, completely forming the capacitor. Herein, the upper electrode is constituted with a metal layer, a silicon layer or a metal layer/poly-silicon layer. Particularly, one of a titanium nitride (TiN) layer and a rubidium (Ru) layer is used for forming the metal layer, and the silicon layer is formed with the undoped poly-silicon layer or the doped poly-silicon layer. At this time, such aforementioned poly-silicon layer is formed by performing a low pressure chemical vapor deposition (LPCVD) process. Also, in case of applying the TiN layer to the metal layer, a single TiN layer is formed through the use of the ALD or CVD process. Also, a dual TiN layer is formed by depositing a second TiN layer by performing the ALD or CVD process after depositing a first TiN layer by carrying out a physical vapor deposition (PVD) process.

According to the preferred embodiment of the present invention, it is possible to form the Al₂O₃ film on the SiO₂ layer deposited on the surface of the lower electrode without spending any incubation time at the initial time of the ALD process. Also, the capacitor containing the Al₂O₃ film in accordance with the present invention has a metal-insulator-silicon (MIS) or silicon-insulator-silicon (SIS) structure. In addition, a formation of the metallic Al cluster is prevented, and a generation of the interface oxide layer is also prevented during the heat treatment process for crystallizing the Al₂O₃ film. Therefore, a leakage current property and breakdown voltage property of the capacitor can be improved, and a stable refresh property can be obtained even at a relatively low capacitance.

What is claimed is:

1. A method for forming a capacitor in a semiconductor device:
forming a lower electrode constituted with a silicon layer on a semiconductor substrate a predetermined process on which a predetermined process has been completed;
forming a uniform silicon oxide layer on the lower electrode by performing an atomic layer deposition (ALD) process;
forming an aluminum oxide (Al₂O₃) film on the silicon oxide layer; and
crystallizing the Al₂O₃ film by carrying out a heat treatment process.

2. The method as recited in claim 1, wherein the silicon oxide layer is formed by performing an atomic layer deposition (ALD) process.

3. The method as recited in claim 1, wherein the silicon oxide layer is formed by using an in-situ method or an ex-situ method.

4. The method as recited in claim 1, wherein a silicon source selected from a group consisting of SiCl₄, DCS and HCD and a reaction source selected from a group consisting of H₂O, O₃ and H₂O₂ are used to form the silicon oxide layer during the ALD process.

5. The method as recited in claim 4, wherein a pyridine acting as a catalyst is used when the silicon source and the reaction source are supplied during the ALD process.

6. The method as recited in claim 4, wherein each of a supply time and a purge time for the silicon source and the reaction source is less than 10 seconds respectively.

7. The method as recited in claim 2, wherein the silicon oxide layer is formed at a low temperature less than about 200° C.

8. The method as recited in claim 7, wherein a thickness of the silicon oxide layer is less than about 10 Å.

9. The method as recited in claim 1, wherein the Al₂O₃ film is formed by performing an ALD process.

10. The method as recited in claim 9, wherein Al(CH₃)₃, which is trimethylaluminum (TMA), is used as an aluminum source, and one of H₂O, O₃ and H₂O₂ is used as a reaction source during the ALD process.

11. The method as recited in claim 10, wherein a plasma is used as an energy source during the ALD process.

12. The method as recited in claim 11, wherein the ALD process is carried out at a room temperature or at a temperature of about 500° C.

13. The method as recited in claim 9, wherein a thickness of the Al₂O₃ film is less than about 100 Å.

14. The method as recited in claim 1, wherein the heat treatment process is carried out at a temperature greater than 600° C and in an N₂ or O₂ ambient.

15. The method as recited in claim 14, wherein the heat treatment process is carried out by using a furnace annealing process or a rapid thermal process (RTP).

16. The method as recited in claim 1, wherein an upper electrode constituted with a metal layer, a silicon layer or a metal layer/silicon layer is formed on an upper area of the crystallized Al₂O₃ film.
